(19) United States
(12) Patent Application Publication
(10) Pub. No.: US 2025/0002272 A1
(43) Pub. Date: Jan. 2, 2025

(54) DEVICE AND METHOD FOR PRODUCING SOLAR MODULES

(71) Applicant: M10 Solar Equipment GmbH, Freiburg (DE)

(72) Inventors: David Blain, Endingen (DE); Michael FEHRENBACH, Waldkirch (DE); Sebastian BLUM, Endingen (DE); Pascal SEITERICH, Freiburg (DE); Frank BAUMANN, Kappel-Grafenhausen (DE); Kilian RINKLIN, Eichstetten (DE); Marco SALADIN, Kirchzarten (DE); Dominique JEHL, Rhinau (FR); Martin SCHULTIS, Waldkirch (DE); Christian REICHLING, Freiburg (DE); Philipp Donatus Martin ZAHN, Freiburg (DE)

(73) Assignee: M10 Solar Equipment GmbH, Freiburg (DE)

(21) Appl. No.: 18/710,270

(22) PCT Filed: Nov. 3, 2022
(86) PCT No.: PCT/EP2022/080726

§ 371 Date: May 15, 2024

(30) Foreign Application Priority Data
Nov. 19, 2021 (DE) 10 2021 130 295.1

(51) Int. Cl. B65G 49/06; H01L 31/18

(52) U.S. Cl. CPC B65G 49/061; H01L 31/188

(57) ABSTRACT

A device (1) for producing solar modules (2) from electrically interconnected solar elements (3), in particular from electrically interconnected solar shingles (3), with a feed device (4) for feeding the solar elements (3) for equipping with solar modules (2), wherein the supply device (4) includes a magnetically guided planar drive (5) with at least two magnetically driven sliders (6), and each slider (6) has a respective workpiece receptacle (8) on which at least one support area (9) for at least one solar element (3) is formed.

### CROSS-REFERENCE TO RELATED APPLICATIONS

This application is a 371 National Phase of International Patent Application No PCT/EP2022/080726, filed Nov. 3, 2022, which claims priority from German Patent Application No. DE 10 2021 130 295.1, filed Nov. 19, 2021.

### TECHNICAL FIELD

The invention relates to devices for producing solar modules from electrically interconnected solar elements, in particular from electrically interconnected solar shingles, wherein the devices have a feed device for feeding the solar elements for the assembly of solar modules.

Furthermore, the invention also relates to methods for producing solar modules in which solar modules are fitted with solar elements, in particular solar shingles.

### BACKGROUND

Devices and methods for producing solar modules from solar elements are already known in practice in a wide variety of embodiments.

A new technique involves assembling solar modules from so-called solar shingles, i.e. shingle-shaped solar cell strips. The solar elements in the finished solar module can be arranged in rows, with one row of solar elements overlapping a neighboring row of solar elements for electrical contacting. In this way, a solar module is provided that has a shingle-like structure.

In this context, it should be mentioned that a row in such a solar module can be a structure of solar elements within which an electrical voltage level is applied. In this case, a row is therefore not a conventional string, as used in other solar modules, in the longitudinal direction of which the electrical voltage build-up takes place via the solar elements combined in the string.

The electrical voltage build-up in such a solar module can take place across neighboring, electrically interconnected rows of solar elements transversely or at right angles to the longitudinal extension of the rows.

### SUMMARY

The object of the invention is to provide devices and methods of the type mentioned at the beginning, which promote the most flexible and yet economical production of solar modules.

To solve the object, a device for producing solar modules from electrically interconnected solar elements, in particular from electrically interconnected solar shingles, is first proposed, which has one or more of the means and features disclosed herein directed to such a device. To solve the object, a device for producing solar modules is thus proposed in particular, which has a feed device for feeding the solar elements for the assembly of solar modules. According to the invention, the device is characterized in that the feed device comprises a magnetically guided planar drive with at least two magnetically driven sliders. Each slider has a workpiece receptacle on which at least one support point, preferably at least two or three support points, is formed for at least one solar element.

The use of a feed device with a magnetically guided planar drive, which has at least two magnetically driven sliders as transport means for transporting the solar elements for fitting a solar module, enables extremely flexible production of solar modules.

It is possible to produce solar modules with different solar panel sizes and/or solar element configurations within one solar module using one and the same solar module production device without the need for complex conversion measures or retooling processes.

In this way, a device is provided that enables extremely flexible production of solar modules without being fixed to a specific solar element size and/or solar element geometry or solar module size and/or solar module geometry.

The device according to the invention makes it possible, for example, to initially manufacture solar modules of a first type in order to subsequently manufacture solar modules of a second solar module type-without complex conversion measures-which differs from the first type in terms of, for example, the number of solar elements per solar module and/or the size and/or geometry of the solar elements and/or the arrangement of the solar elements within the solar module.

In one embodiment of the device, it is provided that at least two support points for at least one solar element each are arranged on each workpiece receptacle. In this way, it is possible to simultaneously feed two or more solar elements for fitting a solar module with one slider of the magnetically guided planar drive. This can increase the productivity of the device

The planar drive can be set up for, preferably independent, multi-coordinate positioning of the at least two sliders.

Preferably, the planar drive for independent multi-coordinate positioning of the at least two sliders has six degrees of freedom. In this way, each of the at least two sliders can be moved independently of one or all of the other sliders of the planar drive in or around up to six axes.

This enables linear movement of the sliders in the X, Y and Z directions, with X, Y and Z representing the spatial coordinates, as well as rotation of the sliders around the three spatial axes X, Y and Z mentioned above. The sliders can therefore be moved in six degrees of freedom using the planar drive.

The magnetically guided planar drive can have a drive surface on which the at least two sliders can be positioned independently of each other in the aforementioned manner in order to feed the solar elements for the assembly of solar modules. The sliders can float on or above the drive surface due to magnetic levitation and be moved by the magnetically guided planar drive.

Below the drive surface, the planar drive can have stands or stators with which the sliders can be positioned on the drive surface.

A transfer area can be defined on the drive surface in which at least two sliders can be positioned next to each other in rows to configure the solar elements arranged on the support points of their workpiece carriers. For this purpose, the sliders can assume individual and/or variable transfer positions as target positions within the transfer area. In this way, it is possible to use the sliders of the planar drive in a very flexible way to arrange the solar elements in a specific configuration even before the solar modules are fitted in the aforementioned transfer area. For example, it is possible to arrange the solar elements in the transfer area in rows that extend over two or more of the sliders in order to then feed the solar elements row by row for the assembly of a solar module.

The device can have a pick-and-place device. With the aid of the pick-and-place device, with which the solar elements arranged on the workpiece receptacles of the sliders can be removed from the support points and preferably placed row by row for the assembly of solar modules. For this purpose, the pick-and-place device can have at least one gripper, preferably at least one suction gripper. The pick-and-place device can be set up to move the at least one gripper in at least two or three degrees of freedom. In one embodiment of the pick-and-place device, it is possible to move the at least one gripper in three spatial axes (X, Y and Z) and about a pivot axis. In this way, it is possible to pick up the solar elements held ready in the transfer position with the aid of the sliders, transport them further in a transfer movement and then deposit them in a desired lay-out arrangement for fitting a solar module on a support, for example on a transport unit, which is explained in more detail below.

In order to be able to deposit the solar elements in rows and/or in an overlapping shingle arrangement, it may be expedient to deposit the solar elements with the aid of the at least one gripper of the pick-and-place device in an oblique orientation, i.e. in an orientation in which their underside forms an acute angle with a base on which the solar elements are to be placed for fitting a solar module. This enables the solar elements to be placed precisely on rows of already placed solar elements in a so-called shingle arrangement when the solar module is assembled. For this purpose, the at least one gripper of the pick-and-place device can be pivotably mounted by means of a pivot joint. In one embodiment of the device, the linear guide can be pivotably mounted via the at least one pivot joint in order to be able to pivot the at least one gripper.

As previously indicated, the device can have a transport unit, for example a conveyor belt. The solar elements for the assembly of solar modules can be placed on the transport unit, in particular on the conveyor belt, preferably in a shingle arrangement. The transport unit can then be used to feed the solar modules fitted with solar elements to a downstream processing and/or handling step. For example, it is possible to use the transport unit to feed the solar elements to a downstream processing step, such as heating the device. In the downstream processing step, the solar elements can be connected to each other or a bond between the solar elements of assembled solar modules can be cured.

The device can have a suction device with a vacuum source and a suction means The suction means can be assigned to the previously mentioned transport unit, on which the solar elements can be placed when assembling solar modules. For example, a suction table connected to the vacuum source of the suction device can be used as the suction means. The transport unit, in particular a conveyor belt, can run over the suction table. It can be advantageous here if the transport unit, in particular the conveyor belt, is permeable to air, in particular perforated. In this way, a vacuum generated by the vacuum source can be transferred via the suction means, in particular via the suction table, to the transport unit and the solar elements positioned thereon in order to fix the solar elements in their arrangement on the transport unit. The suction means can therefore be set up to fix solar elements placed on the transport unit by applying pressure to the transport unit. This is advantageous because, although the solar elements placed on the transport unit for the assembly of the solar modules are connected to each other, for example row by row, by the application of electrically conductive adhesive, the adhesive connection between the solar elements may not yet be fully cured, so that slippage of the solar elements on the transport unit cannot be completely prevented by the adhesive connection.

The suction means, in particular the suction table, can extend into an effective area of a heater of the device, which is provided for curing an adhesive bond between solar elements of an assembled solar module, and into and/or through which the solar elements can be transported with the aid of the transport unit.

The aforementioned drive surface of the planar drive can be formed between a supply station for solar elements and the pick-and-place device. In the supply station of the device, solar elements can be stored in stacks, for example. The solar elements can be picked from the supply station and placed on the support points on the workpiece receptacles of the sliders and then fed for fitting the solar modules.

The device can have at least one handling device with at least one gripper, in particular with at least one suction gripper. With the aid of the handling device, solar elements can be placed one after the other or simultaneously on the support points of the workpiece receptacles of sliders in the pick-up position.

The device can have an alignment determination device for determining the alignment of the solar elements on the aforementioned handling device. The alignment determination device can be an optical alignment determination device and can, for example, have a camera. For example, it is possible to determine the alignment of the solar elements on the handling device using an outer contour of the solar elements and/or using an imprint that the solar elements may bear. Information about the determined alignment of the solar elements can be used for the correct placement of the solar elements on the support points on the workpiece receptacles of the sliders.

The device, in particular the planar drive, can have a control unit. The control unit can be set up to position a slider on the handling device in accordance with a determined alignment of a solar element so that the solar element comes to rest in the desired alignment on a support point of the workpiece receptacle of the slider when the solar element is placed.

This ensures that the solar elements placed on the support point on the workpiece receptacle of a slider are positioned correctly and in the correct alignment for fitting the solar module on the workpiece receptacle. Realignment of the solar elements on and/or by the handling device can thus be avoided.

The device can comprise an adhesive station which has at least one dispensing nozzle for dispensing electrically conductive adhesive onto a solar element arranged at a support point. The at least one dispensing nozzle can be arranged above one, for example above the aforementioned drive surface of the planar drive.

In order to be able to apply electrically conductive adhesive to the solar elements, it is possible to move the solar elements past the dispensing nozzle using the sliders and apply the electrically conductive adhesive to the solar elements in the process.

The use of a magnetically guided planar drive and the sliders is also advantageous in connection with the application of the electrically conductive adhesive.

Due to the large number of degrees of freedom in which the sliders can also be moved during the dispensing of the electrically conductive adhesive onto the solar elements, it is possible to influence certain application parameters during the application of the electrically conductive adhesive via the positioning of the sliders and the solar elements arranged thereon relative to the at least one dispensing nozzle.

For example, it is possible to move the sliders with the solar elements arranged thereon past the at least one dispensing nozzle at different speeds in order to adjust the application of the conductive adhesive. Furthermore, it is possible to adjust the distance between the at least one support point on the workpiece carrier of the sliders and the at least one dispensing nozzle by moving the slider accordingly in the direction of a Z-axis, which can be aligned vertically This can also influence the application of the electrically conductive adhesive to the solar elements.

Preferably, the adhesive station has a number of dispensing nozzles that corresponds to a number of support points on a workpiece carrier of a slider. At least two of the existing dispensing nozzles can be arranged offset to one another in the direction of movement of the sliders through the adhesive station. The staggered arrangement of the at least two dispensing nozzles makes it possible to arrange the dispensing nozzles as desired, regardless of their installation space, in order to be able to apply beads of electrically conductive adhesive with only a small distance even to comparatively narrow solar elements.

The device can have at least one testing station, which is set up for testing an adhesive application on the solar elements arranged on the tool receptacles and/or for testing the solar elements arranged on the tool receptacles. The testing station can be provided at or on a drive surface of the planar drive, for example at or on the previously mentioned drive surface.

With the aid of the sliders, the solar elements arranged on the tool receptacles can be fed to the testing station, preferably after an application of electrically conductive adhesive, which can be carried out at an adhesive station, for example at the aforementioned adhesive station, and tested there accordingly. The testing station can have at least one sensor that is set up to test the solar elements and/or an adhesive application on the solar elements

Preferably, the testing station has a number of sensors that corresponds to a number of support points for solar elements on a tool receptacle of a slider. In this way, it is possible to check all solar elements positioned on a tool receptacle of a slider at the same time to see whether the solar elements and/or an adhesive application on them are all right or not.

An optical sensor, such as a fork light barrier or a camera, can be used as a sensor However, it is also possible to use mechanical sensors, such as touch sensors, as sensors.

A removal device can be assigned to the testing station. The removal device can be adapted to eject improper solar elements. The removal device can have at least one gripper, in particular at least one suction gripper. If an inspection of the solar elements and/or the adhesive application on the solar elements shows that a solar element and/or an adhesive application on it is/are not correct, the affected solar element can be removed from the tool receptacle of the slider using the removal device and ejected from the production process. This helps to ensure that, as far as possible, only correct solar elements are fed for the assembly of solar modules. This can considerably improve the production quality that can be achieved with the device and significantly reduce the reject rate of the solar modules produced.

The device can have an electrostatic station. The electrostatic station can be set up for electrostatically charging and/or electrostatically discharging the workpiece carriers of the sliders. In this way, it is possible to fix solar elements to the workpiece receptacles using electrostatic charge when feeding them for the assembly of solar modules. With the help of electrostatic transport fixing, contactless fixing of the solar elements to the workpiece carriers is possible, which makes it possible to dispense with comparatively complex mechanical clamping devices.

For reliable electrostatic fixing of the solar elements to the workpiece receptacles of the sliders, it can be advantageous to first completely discharge the workpiece receptacles electrostatically. This can be done using at least one discharging contact of the electrostatic station. The electrostatic station can have at least one charging contact with which the workpiece receptacles of the sliders can be electrostatically charged to a desired value.

Preferably, the at least one charging contact and/or the at least one discharging contact of the electrostatic station can be arranged or designed to be stationary and/or immovable on the electrostatic station of the device. This can considerably simplify the design of the electrostatic station.

A relative movement between the charging contact or discharging contact and the workpiece receptacles of the sliders can in turn be caused by the magnetically guided planar drive and the sliders.

In order to be able to discharge the workpiece receptacles with the aid of the at least one discharging contact, the sliders can bring the workpiece receptacles into contact with the at least one discharging contact of the electrostatic station. It is also possible to bring the workpiece receptacles of the sliders into contact with the at least one charging contact of the electrostatic station by a corresponding movement of the sliders in order to electrostatically charge the workpiece receptacles to a desired value.

In one embodiment of the device, the workpiece receptacles of the sliders are adapted to receive a matrix pattern consisting of a plurality of solar elements. In this way, it is possible to already have a matrix pattern of individual solar elements, which corresponds to at least a partial pattern of a solar module to be fitted, ready for the fitting of a solar module on the workpiece receptacles of the sliders.

The device can have at least one testing device for testing the solar elements for damage and/or dimensional accuracy and/or geometry. The testing device can be mounted upstream of a drive surface of the planar drive, for example the one mentioned above. In this way. it is possible to eject improper solar elements before they are placed on the support points on the workpiece receptacles and fed to the assembly of the solar modules.

To solve the object, a device having one or more of the features disclosed herein is also proposed, which has a pick-and-place device, for example the previously mentioned pick-and-place device, with which solar elements held ready in an output arrangement can be picked up and placed in a defined target arrangement for the assembly of a solar module. The pick-and-place device has at least two groups of grippers, in particular suction grippers, the distance between which can be varied in order to pick up the solar elements in an output arrangement and deliver them in a target arrangement, which differs from the output arrangement, for the assembly of a solar module.

For this purpose, the pick-and-place device can have a linear guide along which the groups of grippers are arranged so as to be displaceable relative to one another. The linear guide can be aligned transversely or at right angles to a transport direction of a transport unit, for example the previously mentioned transport unit downstream of the pick-and-place device, and/or can itself be movable in this transport direction.

The groups of grippers can thus be movable, in particular along the linear guide, in a first direction and/or transversely or at right angles to a transport direction of a transport unit downstream of the pick-and-place device, for example the transport unit already mentioned above, on which the solar module is assembled with solar elements. Furthermore, it is also possible for the groups of grippers to be movable transversely or at right angles to the direction of movement specified by the aforementioned linear guide. For this purpose, the pick-and-place device can have a transfer guide, in particular a gantry, along which the groups of grippers are displaceable in a second direction. The second direction can be oriented transversely or at right angles to the first direction.

In this way, it is possible to pick up the solar elements using the pick-and-place device from a transfer position in which they are held ready for placement on the solar module and to place them in a desired manner for the assembly of solar modules and, optionally, to reposition them and/or combine them into a row by means of a relative movement of the at least two groups of grippers. In this way, a wide variety of laying patterns of solar elements can be produced during the assembly of solar modules.

To solve the object, a method for producing solar modules is also proposed, wherein solar modules are fitted with solar elements, in particular with solar shingles, which has at least one of the means and features disclosed herein directed to such a method. To solve the object, it is thus proposed in a method for producing solar elements that the solar elements are fed for the assembly of a solar module with magnetically driven sliders of a magnetically guided planar drive.

In this context, the solar elements can be arranged in at least one row with the sliders, in particular in a transfer position in a transfer area on a pick-and-place device. It is also possible to transport the solar elements with the sliders to a transfer position in a transfer area on a pick-and-place device. With the aid of the extremely flexible sliders of the magnetically guided planar drive, it is possible to feed the solar elements for the assembly of solar modules in almost any arrangement and relative orientation to each other and to provide them for the assembly of solar modules.

For the assembly of solar modules, the solar elements can be placed on a transport unit. The transport unit can be designed as a conveyor belt, for example. The transport unit can be used to feed the solar modules fitted with solar elements to a subsequent processing step. For example, it is possible to feed the solar modules fitted with solar elements to a heater using the transport unit in order to cure an adhesive bond, which will be explained in more detail below, between the solar elements or between rows of solar elements of the solar modules. In this context, it can be useful to fix the solar elements of the assembled solar modules to the transport unit by means of negative pressure until the adhesive bonds have cured. The aforementioned heating can be used to cure the adhesive bonds between the solar elements, in particular between the rows of solar elements, of the assembled solar modules.

The solar modules can be placed, for example with a handling device, on support points on workpiece receptacles of the sliders. The handling device can, for example, be a handling device of the aforementioned device for producing solar modules.

It is possible to determine the alignment of the solar elements before they are placed on the support points. The sliders can then be controlled and aligned in accordance with the determined alignment of the solar elements before the solar elements are placed on the support points so that the solar elements are placed on the support points in the correct alignment without changing their alignment on the handling device.

A possible misalignment of the solar elements can thus be compensated for when they are placed on the support points by positioning the sliders accordingly, so that the solar elements are correctly arranged on the support points after placement.

The sliders can be moved in and/or around at least one of up to six axes according to their up to six degrees of freedom.

In one embodiment of the method, it is provided that electrically conductive adhesive is applied from at least one dispensing nozzle of an adhesive station, preferably on the edge of solar elements positioned on the support points of the workpiece receptacles of the sliders. The adhesive can be applied during a transfer movement of the slider relative to the dispensing nozzle. Furthermore, it is possible to set a defined distance between the solar elements under at least one dispensing nozzle by moving the slider along a preferably vertical axis of movement of the slider. In this way, it is possible to influence the application parameters when applying the electrically conductive adhesive to the solar elements in the desired manner by a targeted movement and/or control of the slider without changing a position of the at least one dispensing nozzle.

In one variant of the method, it is provided that the solar elements are fed to a testing station with the sliders for testing, in particular of an adhesive application on or to the solar elements. The testing station can be arranged or formed in the area of the previously mentioned drive surface of the device.

The solar elements and/or an adhesive application on the solar elements can be tested in the testing station. Solar elements that are not in order, for example those that have a defect or to which an adhesive has not been properly applied, can then be removed from the tool receptacles of the sliders using a removal device of the device, for example the one mentioned above, and ejected from the production process.

In one embodiment of the method, the workpiece receptacles of the sliders can be loaded with solar elements and moved with the sliders into a transfer position in such a way that solar elements on two sliders arranged next to each other in the transfer position form at least one row of solar elements. In this way, it is possible to feed the solar elements in rows for an assembly of solar modules and to keep them assembled in rows ready for the assembly of solar modules. In particular, this can facilitate the previously explained production of solar modules using the shingle construction method or the so-called shingle-matrix construction method, in which a row of solar elements within a solar module overlaps an adjacent row at the edge in order to establish electrical contact with the adjacent row of solar elements.

In one embodiment of the method, it is provided that in order to generate a matrix arrangement, in particular a shingle-matrix arrangement, at least one offset element, i.e. a solar element with shorter dimensions than the other solar elements within a row, is provided in at least every second row of solar elements which is held ready in the transfer position for the assembly of the solar modules.

In this context, it should be explained that a matrix arrangement of solar elements can represent an arrangement of solar elements in which the solar elements are arranged with a row-by-row offset to one another, as in a brickwork. In this way, it is possible for a solar element in one row to overlap at least two solar elements in a neighboring row. This promotes the formation of alternative current paths within a solar module constructed in this way.

The workpiece receptacles of the sliders can be electrostatically charged to fix the solar elements in place on the support points during transportation. This is preferably done to a defined value. It is possible to discharge the workpiece receptacles electrostatically beforehand. The workpiece receptacles can be brought into a contact position with the charging contact and/or the discharging contact by moving the sliders relative to a charging contact and/or relative to a discharging contact of an electrostatic station. It is advantageous to first discharge the workpiece receptacles, which can be caused by a short circuit, for example, in order to then electrostatically charge the workpiece receptacles as precisely as possible to a defined value. The degree of electrostatic charge of the workpiece receptacle can determine the holding force of the electrostatic transport fixation, with which the solar elements can be fixed to the workpiece receptacles of the sliders when the solar elements are fed to the support points for the assembly of a solar module.

In one embodiment of the method, it is provided that at least one slider executes an evasive movement before moving a slider into its target position next to a slider already in the transfer position in order to avoid a collision between solar elements placed at the support points of the workpiece receptacles of the sliders.

It may be provided that the evasive movement of the at least one slider is a tilting movement about a movement axis of the at least one slider. However, it is also possible to move at least one slider along a spatial axis, for example in the Z direction, in order to create space for a slider to move into its target position adjacent to another slider. At least one slider, for example the slider that is to be moved into its target position, can be raised or lowered. When performing a tilting movement, it is possible for the tilting movement to take place around a movement axis that is aligned in the direction of movement of one slider into its target position.

In one embodiment of the method, it is provided that a slider is raised or lowered and/or tilted about a movement axis, in particular about an axis aligned in the direction of its movement into the target position, before being moved into its target position between two sliders already in the transfer position, in order to avoid a collision between the at least one solar element arranged on its workpiece receptacle and the solar elements arranged on the workpiece receptacles of the sliders already in the transfer position. However, it is also possible to raise or lower the two sliders, between which one slider is to be moved into its target position, beforehand or to tilt them accordingly in order to avoid a collision of the solar elements on the workpiece carriers of the sliders.

In one embodiment of the method, it is provided to arrange solar elements in a matrix arrangement, namely in at least two rows and/or offset from one another, on a workpiece receptacle of at least one slider. In this way, it is possible to feed the solar elements for the assembly of the solar module already in a matrix arrangement, which can also be found in the subsequently manufactured solar module.

To solve the object, a method having one or more of the means and features disclosed herein, directed to a method for producing solar modules, is also proposed. Itis provided that solar elements are fed for the assembly of a solar module by transport means, in particular by sliders of a magnetically guided planar drive, wherein solar elements are jointly picked up by at least two transport means located in a transfer position and are combined to form a row of solar elements for the assembly of a solar module. It may be provided that the solar elements are combined into a row and placed on a transport unit, for example on the previously mentioned transport unit.

On the transport unit, the solar elements can be fixed for transport by means of negative pressure and/or fed to a heater of the aforementioned device. The heating can be used to cure adhesive bonds between the solar elements, in particular between the rows of solar elements, of the assembled solar modules.

The solar elements can be picked up together with at least two groups of grippers of a pick-and-place device and combined into a row of solar elements by a relative movement of the groups of grippers.

When assembling a solar module, the solar elements can be placed and/or glued together in overlapping rows, in particular on a transport unit. The solar elements can be placed on a transport unit, for example on the aforementioned transport unit. The placed solar elements can be fixed by means of negative pressure, for example on the transport unit. A suction device, for example the aforementioned suction device with its vacuum source and a suction means, can be used for this purpose.

It is possible for the solar elements to be placed during the assembly of a solar module in such a way that they overlap solar elements that have already been placed. It is also possible to place the solar elements in rows overlapping an already placed row of solar elements when assembling a solar module.

When assembling a solar module, the solar elements can be placed on already positioned solar elements in such a way that their underside forms an acute angle with a base on which the solar elements are to be placed for the assembly of solar modules. In this way, the solar elements can be placed on a shingle arrangement created during the overlapping placement of the solar elements. By placing the solar elements at an angle on already positioned solar elements as described above, this can be done with particularly high positioning accuracy.

Finally, to solve the object, the use of a device for producing solar modules according to one or more of the features disclosed herein for carrying out a method for producing solar modules according to one one or more of the features disclosed herein is also proposed.

### BRIEF DESCRIPTION OF THE DRAWINGS

The invention is described in more detail below with reference to exemplary embodiments, but is not limited to these exemplary embodiments. Further exemplary embodiments result from combining the features of individual or several claims with one another and/or in combination of individual or several features of the exemplary embodiments, wherein:

FIG. 1: shows a perspective view of a device for producing solar modules, which has a feed device with a magnetically guided planar drive and a plurality of sliders that can be freely positioned on a drive surface of the planar drive with the aid of the planar drive, which are used as transport means to feed solar elements for the assembly of solar modules,

FIGS. 2 and 3: show detailed views of the magnetically guided planar drive with sliders arranged on it to illustrate the degrees of freedom in which the sliders can be moved when feeding the solar elements for the assembly of solar modules,

FIGS. 4-7: show different views illustrating evasive movements that can be carried out with the help of the sliders when moving the sliders to the transfer position for the assembly of a solar module with solar elements in order to avoid collisions between solar elements arranged on workpiece receptacles of the sliders,

FIGS. 8-14: show different views to illustrate the placement of solar elements on support points on workpiece receptacles of the sliders,

FIG. 15: shows a detailed view of an adhesive station of the device shown in FIG. 1, wherein the adhesive station has a total of three dispensing nozzles arranged offset to one another in the direction of transportation of the sliders through the adhesive station.

FIG. 16: shows a side view of the adhesive station shown in FIG. 15 to illustrate the application of a first adhesive bead of electrically conductive adhesive to a first of three solar elements arranged on the workpiece receptacle of the slider.

FIG. 17: shows a side view of the adhesive station shown in FIGS. 15 and 16 to illustrate the application of an adhesive bead of electrically conductive adhesive to a middle one of the three solar elements positioned on the support points of the workpiece receptacle of the slider,

FIG. 18: shows a side view of the adhesive station shown in FIGS. 15 of 17 to illustrate the application of a third adhesive bead of electrically conductive adhesive to a third solar element on the workpiece receptacle,

FIGS. 19 and 20: show views illustrating the adhesive beads of electrically conductive adhesive applied to the edges of the solar elements,

FIG. 21: shows a detailed view of an electrostatic station for electrostatically discharging and charging the workpiece carriers for the purpose of fixing the solar element to the support points of the workpiece receptacles of the sliders,

FIGS. 22-24: show detailed views of the electrostatic station to illustrate a movement of the sliders to bring the workpiece carriers into a contact position with the discharging contacts of the electrostatic station,

FIGS. 25-27: show detailed views of the electrostatic station to illustrate a movement that the sliders perform to bring their workpiece carriers into a contact position on the charging contacts of the electrostatic station in order to electrostatically charge the workpiece receptacles to a defined value.

FIGS. 28-31: show detailed views of a transfer area of the device shown in FIG. 1 on a pick-and-place device, with the aid of which the solar elements are fed for the assembly of solar modules,

FIGS. 32-43: show different side views of pick-and-place devices to illustrate the assembly of solar modules with solar elements, which are held ready in the transfer position with the aid of the sliders of the planar drive,

FIG. 44: shows a detailed view of the transfer area of the device on a pick-and-place device for the assembly of solar modules with solar elements, wherein it can be seen that the workpiece receptacles of the sliders are covered with solar elements arranged in a matrix or masonry arrangement, wherein the arrangement of the solar elements on the workpiece receptacles of the sliders is reflected in the solar modules fitted with solar elements on a transport unit of the device,

FIG. 45: shows a further detailed view of a transfer area of the device shown in FIG. 1, wherein it can be seen here that each slider has an arrangement and number of solar elements on its workpiece carrier which corresponds to the arrangement and number of solar elements in the solar modules fitted with solar elements on the transport unit.

FIGS. 46-49: show a further detailed view of a pick-and-place device which can be used on the device shown in FIG. 1 and which has a linear guide with a total of four groups of grippers arranged thereon, wherein the groups of grippers for the assembly of solar modules with solar elements held ready on sliders of a planar drive are movable independently of one another along a linear guide relative to one another.

FIG. 50: shows a single representation of a testing station of the device for testing the solar elements and/or an adhesive application on the solar elements, and

FIG. 51: shows an enlarged view of the detail marked with the circle in FIG. 50.

### DETAILED DESCRIPTION

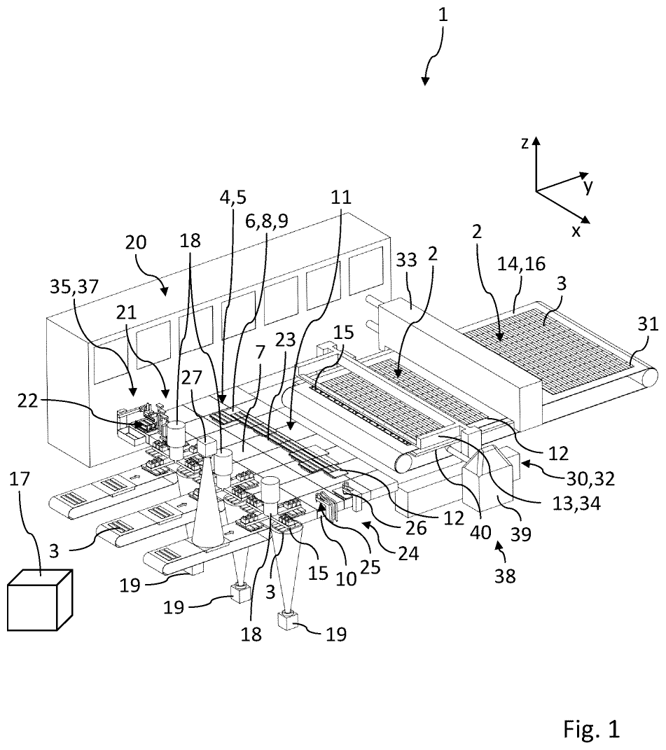

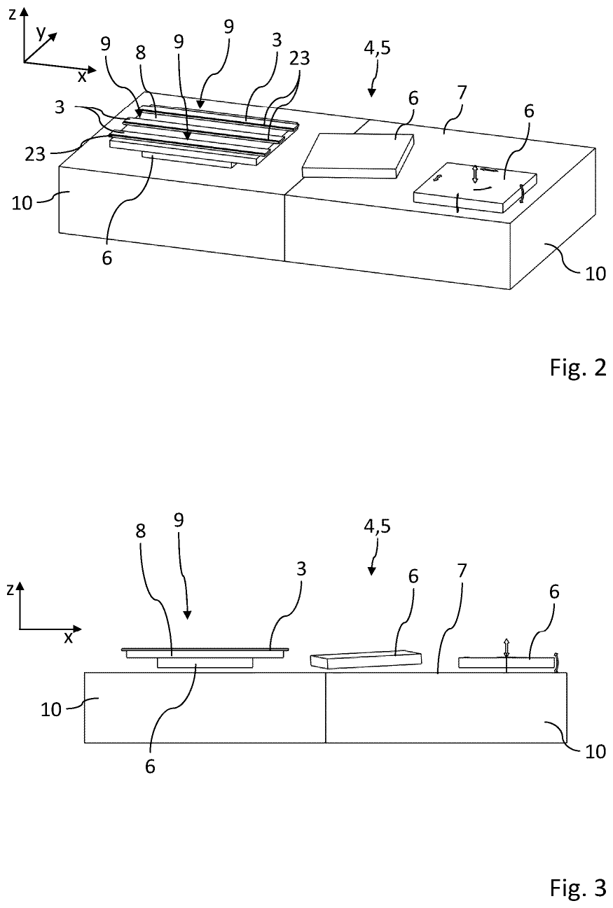

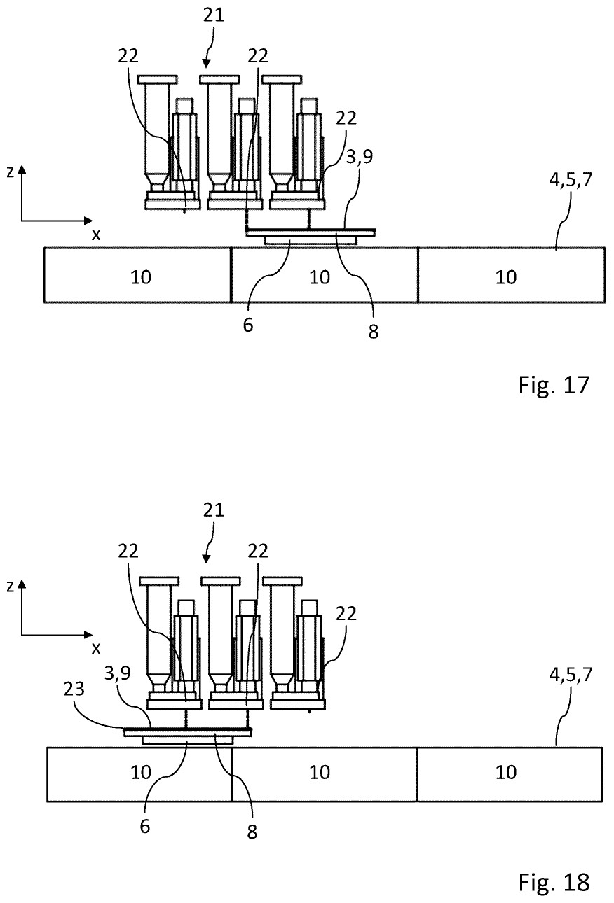

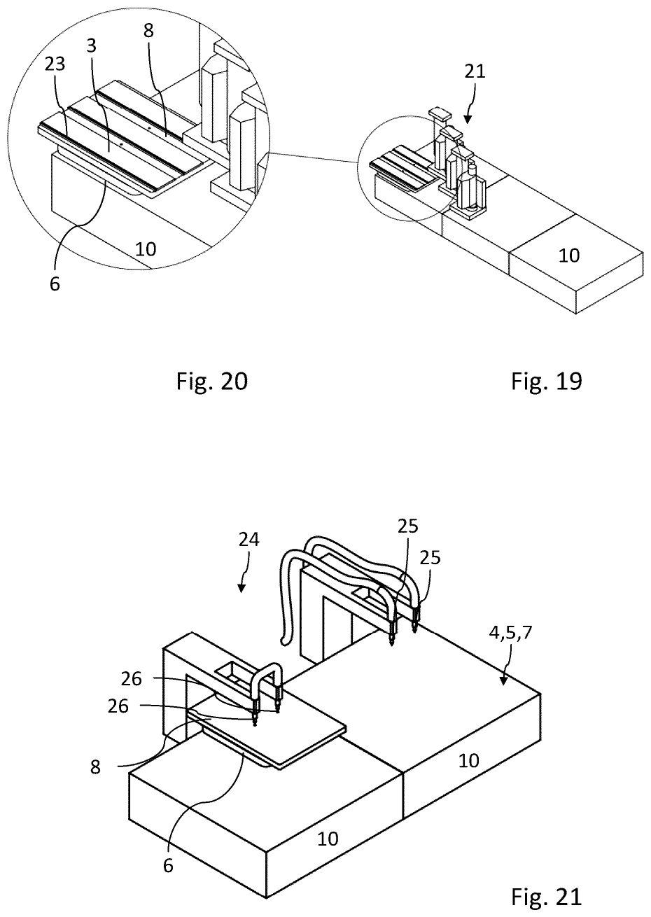

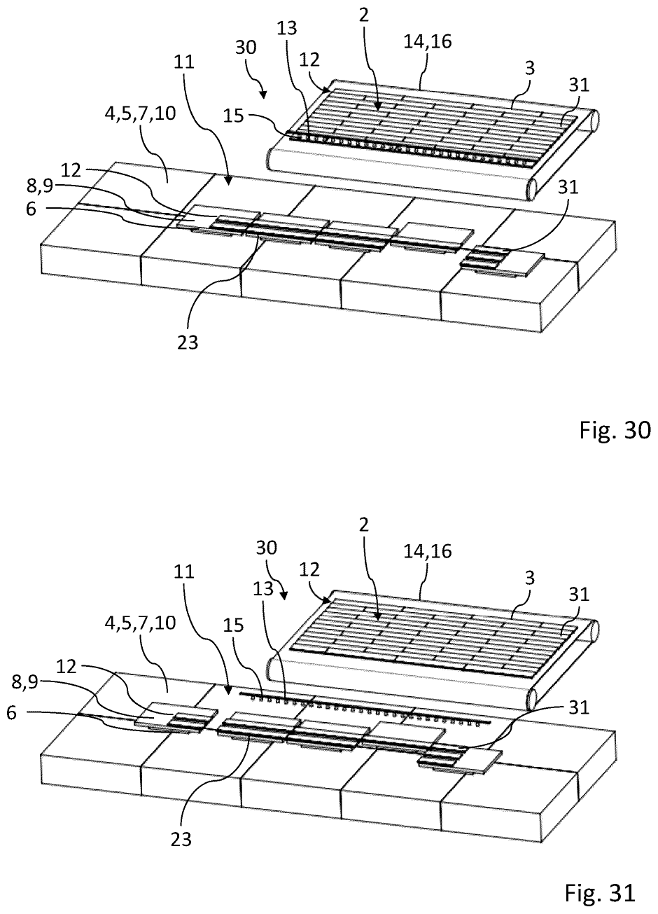

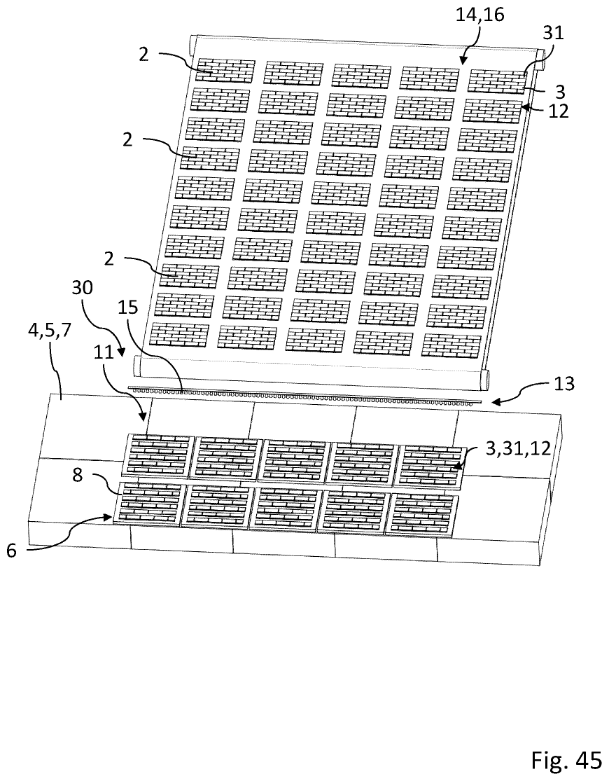

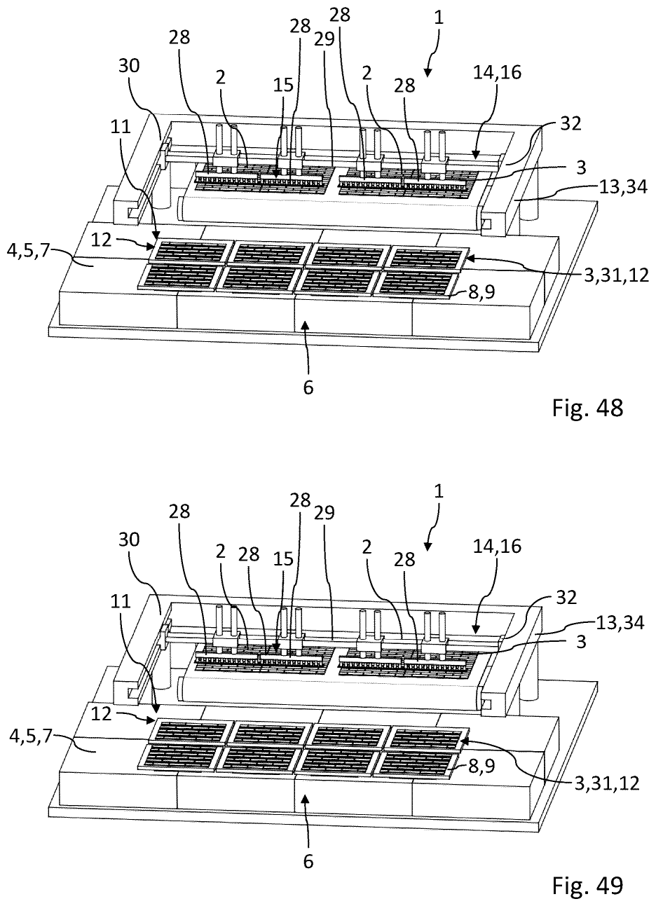

FIG. 1 shows a device, designated 1 in its entirety, for producing solar modules 2 from electrically interconnected solar elements 3, namely from electrically interconnected solar shingles. The remaining FIGS. 2-49 show individual functional units or sections of the device 1 in individual illustrations.

The device 1 has a feed device 4 for feeding the solar elements 3 for an assembly of solar modules 2.

The feed device 4 comprises a magnetically guided planar drive 5 with a plurality of magnetically driven sliders 6, which can be positioned freely and independently of one another in six degrees of freedom on a drive surface 7 of the planar drive 5.

Each of the sliders 6 has a workpiece receptacle 8, on which support points 9 are formed for at least one solar element 3. 31. The planar drive 5 is set up for multi-coordinate positioning of the sliders 6 in six degrees of freedom.

Solar elements 3 are solar elements that are longer than solar elements 31, which can also be referred to as offset elements. Together, the solar elements 3 and 31 can be used to manufacture solar modules 2 in the so-called matrix shingle construction. The solar elements 3 and 31 can therefore also be referred to as solar shingles or solar cell strips.

The magnetically guided planar drive 5 has the aforementioned drive surface 7, on which the sliders 6 can be positioned independently of each other. The drive surface 7 is formed from individual drive modules 10 of the planar drive. The drive modules 10 can have or contain drive units, for example columns and/or stators of the planar drive 5.

A transfer area 11 is defined on the drive surface 7. This transfer area 11 is shown in more detail in FIGS. 1, 28-33 and 44-49, for example.

In the transfer area 11, a plurality of sliders 6 can be positioned next to each other in rows 12 to configure the solar elements 3 to be arranged on the support points 9 of their workpiece receptacles 8.

Adjacent to the transfer area 11, the device 1 has a pick-and-place device 13. With the aid of the pick-and-place device 13, the solar elements 3 arranged on the sliders 6 can be removed from the support points 9 and placed on a base 14, for example, row by row for the assembly of solar modules 2

Each of the pick-and-place devices 13 shown in the figures has at least several grippers 15 for this purpose. All grippers 15 shown in the figures are designed as suction grippers, which allow gentle handling of the solar elements 3.

The solar elements 3 are placed on a transport unit 16, which is designed as a conveyor belt, of the device 1 for the assembly of solar modules 2. The conveyor belt 16 serves as a base 14 on which the solar elements 3 can be placed for the assembly of the solar modules 2.

The figures, which show the transport unit 16 and the base 14, illustrate that the solar elements 3 for the assembly of solar modules 2 are placed in a shingle arrangement and in an arrangement that is similar in structure to masonry and can also be referred to as a matrix arrangement or matrix-shingle arrangement.

It is provided that the solar elements 3 of one row 12 overlap solar elements 3 of an adjacent row 12 in such a way that one solar element 3 of an overlapping row overlaps two solar elements 3 of an adjacent row 12.

FIG. 1 shows that the device 1 has a suction device 38. The suction device 38 comprises a vacuum source 39 and a suction means 40 associated with the transport unit 16, which is designed as a suction table in the exemplary embodiment of the device 1 shown in FIG. 1. The transport unit 16 is designed as a perforated and therefore air-permeable conveyor belt, which is guided over the suction means 40. The suction means 40 is arranged underneath the transport unit 16 and is designed to fix solar elements 3 placed on the transport unit 16 by pressing them against the transport unit 16. The suction means 40 extends into an effective range of a heater 33 of the device 1. The heater 33 is used to cure an adhesive connection between solar elements 3 of an assembled solar module 2.

On the transport unit 16, the solar elements 3 are thus fixed in place during transport by means of negative pressure and fed to the heater 33. The heater 33 cures the adhesive bonds between the solar elements 3, in particular between the rows 12 of solar elements 3, of the assembled solar modules 2.

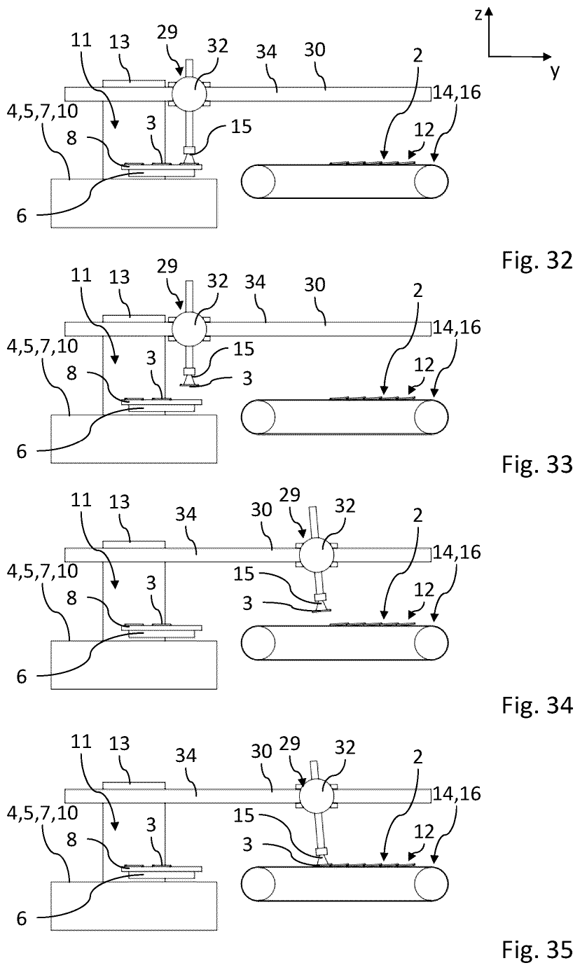

In order to be able to place the solar elements 3 particularly precisely in the aforementioned shingle arrangement when assembling solar modules 2, the grippers 15 of the pick-and-place device 13 shown in FIGS. 33-44 are movable in several degrees of freedom. It is thus possible to deposit the solar elements 3, as shown in FIGS. 32-35 on the one hand and 36-43 on the other hand, with the grippers 15 held in an inclined position precisely on solar elements 3 already placed on the base 14, preferably in rows in a shingle arrangement.

FIG. 1 illustrates that the drive surface 7 of the planar drive 5 is formed between a supply station 17 for solar elements 3 and the previously explained pick-and-place device 13. The drive surface 7 is used, among other things, to position the solar elements 3, which can be fed to the assembly of solar modules 2 with the aid of the sliders 6 of the planar drive 5, in a desired arrangement optimized for the assembly of solar modules 2 in the transfer area 11 of the drive surface 7 adjacent to the assembly device 13.

Due to the free positionability of the sliders 6 on the drive surface 7 of the planar drive 5, it is possible to prepare almost any laying pattern that is to be produced when assembling solar modules 2 with the solar elements 3 by providing the solar elements 3 in the transfer area 11 with the help of the sliders 6.

The device 1 also has three handling devices 18, each comprising a plurality of grippers 15 on four arms, which are also designed as suction grippers. With the aid of the handling devices 18, it is possible to place solar elements 3 one after the other or simultaneously on the support points 9 of the workpiece receptacles 8 of the sliders 6 in the pick-up position.

The free positionability of the sliders 6 in six degrees of freedom is explained in more detail in FIGS. 2 and 3. Here it can be seen that the sliders 6 can be moved in the X, Y and Z directions on the drive surface 7 of the planar drive 5. Furthermore, it is also possible to tilt, rotate or pivot the sliders 6 about each of the three axes mentioned above.

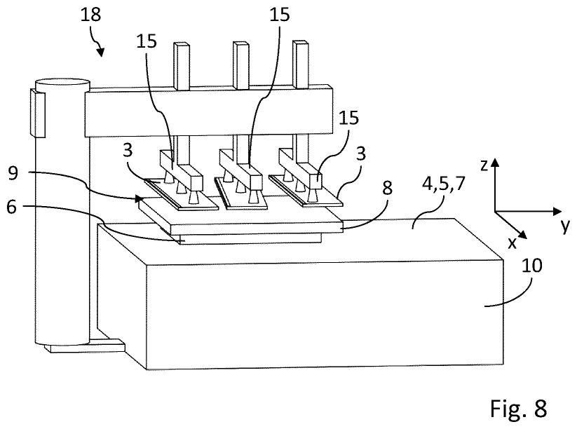

The placement of the solar elements 3 on the support points 9 on the workpiece receptacles 8 of the sliders 6 is shown in more detail in FIGS. 8-15.

The device 1 has a plurality of optical alignment determination devices 19 for determining the alignment of the solar elements 3 on the handling devices 18. Using the outer contours of the solar elements 3 and/or using imprints on the solar elements 3, the alignment determination devices 19 make it possible to determine the specific alignment of the solar elements 3 held on the handling devices 18 and their grippers 15 before the solar elements are placed on the sliders 6 in the pick-up position.

The device 1, in particular the planar drive 5, comprises a control unit 20. The control unit 20 is set up to position the sliders 6 in their pick-up position adjacent to the handling devices 18 as a function of a determined alignment of a solar element 3 on the handling devices 18 in such a way that the solar elements 3 can be placed on one of the support points 9 of the workpiece receptacles 8 of the sliders 6 in accordance with their alignment without realignment of the handling devices 18. Before depositing the solar elements 3 for the receiving thereof, the sliders 6 are brought into an alignment in which they can receive the solar elements 3 at the grippers 15 of the handling devices 18 in accordance with the specifically determined alignment of the solar elements 3 so that they can be properly placed on the support points 9 of the workpiece receptacles 8 of the sliders 6.

FIG. 8 shows a slider 6 in the pick-up position on a handling device 18. The handling device 18 has a plurality of grippers 15 and is set up to hold a total of three solar elements 3 simultaneously.

FIG. 8 shows that each solar element 3 of the three solar elements 3 is arranged on the grippers 15 in a different orientation. With the aid of the six degrees of freedom of movement of the sliders 6, it is possible to align the slider 6 according to the orientation of the solar elements 3 on the handling device 18 before picking up the individual solar elements 3. The aim is to position the solar elements 3 correctly in the alignment gripped by the gripper 15 directly on one of the support points 9 of the workpiece receptacle 8 of the slider without time-consuming repositioning or repeated handling.

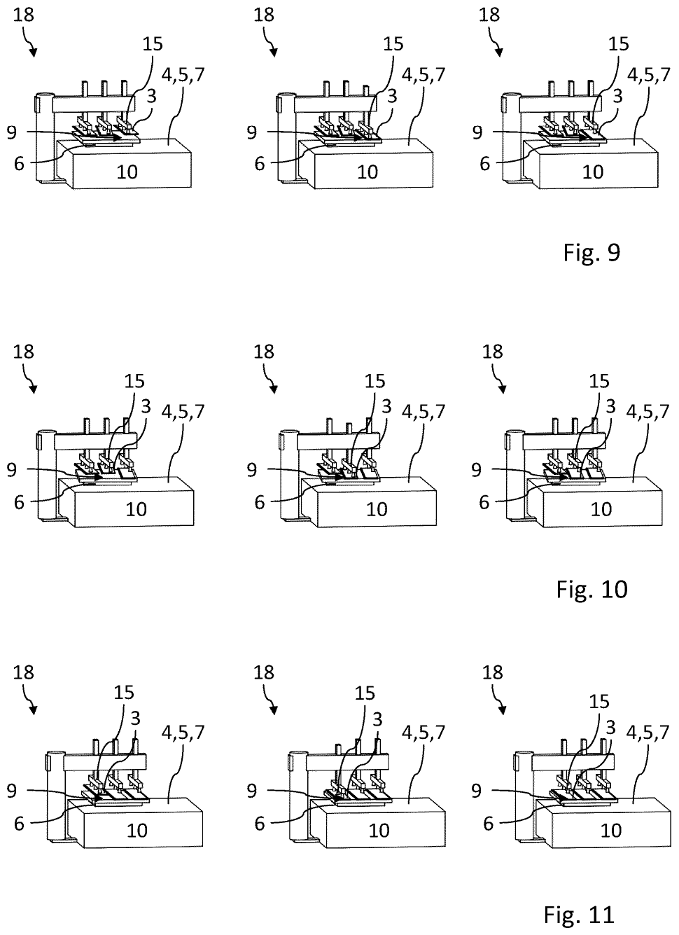

For this purpose, the slider 6 according to FIG. 9 is positioned in a first alignment on the handling device 18 depending on the alignment of a first solar element 3 and the first solar element 3 is placed on a first support point 9 on the workpiece receptacle 8 of the slider 6.

FIG. 10 shows the same procedure with regard to a second solar element 3, which is held ready for depositing on the handling device 18. Depending on the alignment of this solar element 3, the slider 6 is aligned accordingly below the gripper 15 and the solar element 3 is then placed on the second support point 9 on the workpiece receptacle 8 of the slider 6.

The third solar element 3, shown in FIG. 11, is placed in the same way. Here too, the slider 6 is aligned depending on the alignment determined with respect to the third solar element 3 on the handling device 18 before the solar element 3 is placed on a support point 9 on the workpiece receptacle 8 of the slider.

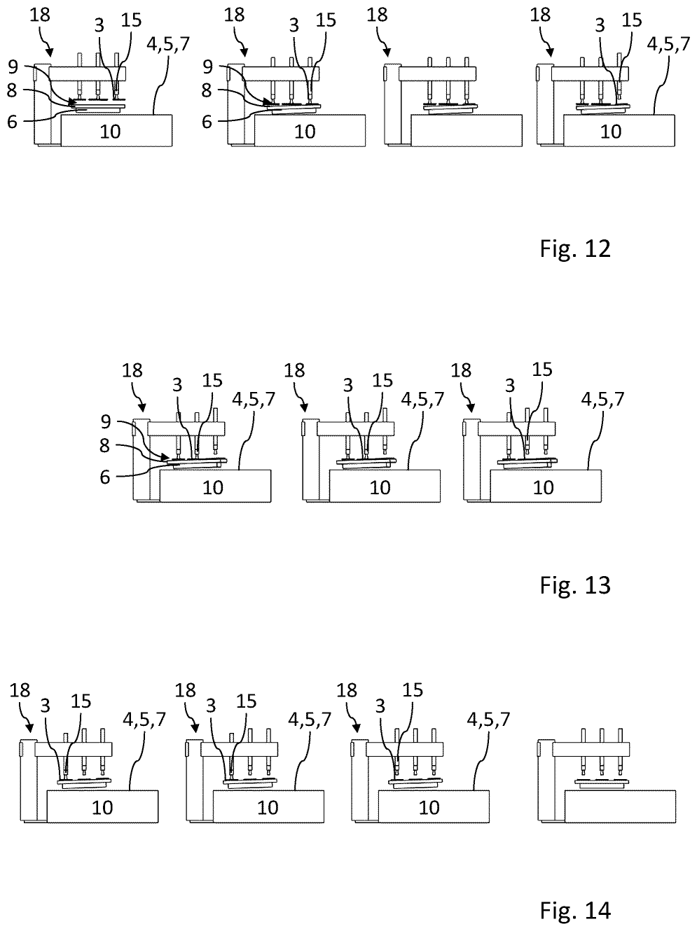

FIGS. 12, 13 and 14 illustrate a further possibility for depositing the solar elements 3 on the support points 9 of the workpiece receptacle 8 of a slider 6. Here it is provided that the slider 6—in addition to the previously mentioned alignment of the slider 6 corresponding to an alignment of the solar elements 3 on the handling device 18—is lifted a little way in the direction of the individual grippers 15 of the handling device 18. To deposit the solar elements 3, the grippers 15 then no longer need to be lowered in the direction of the support points 9, as shown in FIGS. 12-14. As the sliders 6 approach the solar elements 3 to be placed by lifting them, the solar elements 3 only need to be released. The grippers 15 can then be moved into a retracted position. This can reduce the cycle times when depositing the solar elements 3 onto the support points 9 on the workpiece receptacles 8 of the sliders 6 and increase the efficiency of the device 1.

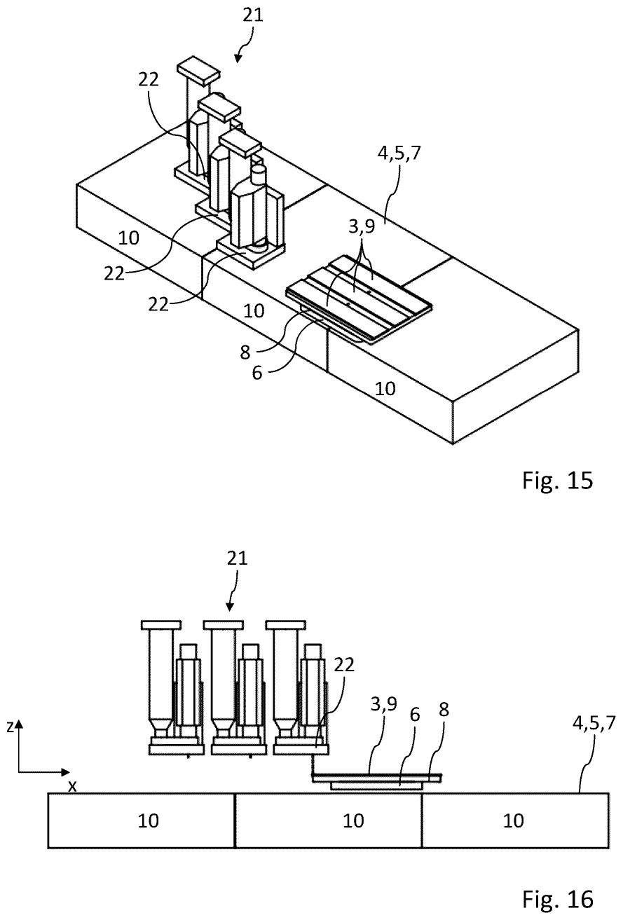

FIGS. 15-20 show detailed views of an adhesive station 21 of the device 1. The adhesive station 21 comprises a total of three dispensing nozzles 22 for dispensing electrically conductive adhesive onto the solar elements 3 arranged at the support points 9 of the sliders 6. The dispensing nozzles 22 are arranged above the drive surface 7 of the planar drive 5 for this purpose, so that the sliders 6 with the solar elements 3 positioned thereon can be moved past below the dispensing nozzles 22 in order to apply the electrically conductive adhesive from the dispensing nozzles 22 to the solar elements 3 in the form of adhesive beads 23.

The adhesive station 21 thus has a number of dispensing nozzles 22, namely three, corresponding to the number of support points 9 on the workpiece receptacles 8 of the sliders 6. The in total three dispensing nozzles 22 are arranged offset to each other in the direction of movement of the sliders 6 through the adhesive station 21. This makes it possible to apply adhesive beads 23 of electrically conductive adhesive to the solar elements 3 positioned on the workpiece receptacles 8 at a comparatively small distance from each other.

FIGS. 15-20 show the application of the adhesive beads 23, with FIG. 20 showing a detailed view of the solar elements 3 with the adhesive beads 23 produced thereon. The application of the electrically conductive adhesive to the solar elements 3 can be specifically influenced by moving the sliders 6 according to at least one of the six degrees of freedom within which each of the sliders 6 can be moved. For example, it may be useful to adjust the distance between the solar elements 3 at the workpiece receptacles 8 of the sliders 6 and the dispensing nozzles 22 of the adhesive station 21 by moving the sliders 6 in the direction of the Z-axis. Furthermore, it is also possible to influence the application of the adhesive beads 23 by adjusting the speed of the sliders 6 at which the sliders 6 are moved through the adhesive station 21.

The adhesive can be applied to the solar elements 3 in different ways. For example. it is possible to apply electrically conductive adhesive to the solar elements 3 in the form of continuous adhesive beads 23. However, it is also possible to apply electrically conductive adhesive to the solar elements 3 in the form of dot patterns or even line patterns or line-dot patterns. This can be carried out at the adhesive station 21 of the device 1 by controlling the dispensing nozzles 22 accordingly. The dispensing nozzles 22 can be controlled by the aforementioned control unit 20.

The device 1 has a testing station 35. The testing station 35 is arranged at or on the drive surface 7 of the planar drive 5. The testing station 35 is used to test an adhesive application on the solar elements 3 arranged on the tool receptacles 8 and also to test the solar elements 3 arranged on the tool receptacles 8.

For this purpose, the testing station 35 has three sensors 36. The sensors 36 are used in particular to check the adhesive application on the individual solar elements 3. In the exemplary embodiment shown in the figures, the sensors 36 are designed as so-called fork light barriers. However, it is also possible to additionally or alternatively use touch sensors and/or cameras as sensors 36.

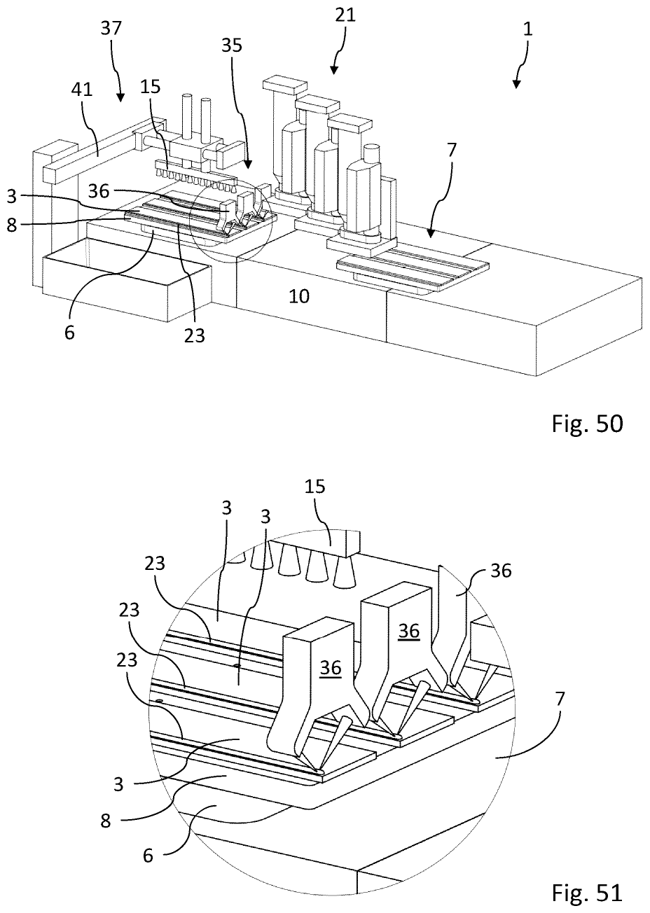

The testing device 35 is located downstream of the adhesive station 21 and is shown in detail in FIGS. 50 and 51. FIG. 50 shows that a removal device 37 is assigned to the testing station 35. The removal device 37 is set up to eject improper solar elements 3. An improper solar element 3 can be one that was tested as improper during the test in the testing station 35, for example because the solar element 3 itself is improper, for example damaged, or because electrically conductive adhesive was not properly applied.

The removal device 37 has a gripper 15, which is designed as a suction gripper. The gripper 15 of the removal device 37 is movable along a linear axis 41 so that it can be used to remove improper solar elements 3 from the tool receptacles 8 and eject them from the production process.

If the inspection of the solar elements 3 fed to the testing station 35 by the sliders 6 shows that the solar elements 3 or the adhesive application on the solar elements 3 is/are not correct, the improper solar elements 3 can be removed from the tool receptacles 8 of the sliders 6 by the removal device 37 and ejected from the production process by a movement of the gripper 15 along the linear axis 41. This helps to ensure that, as far as possible, only correct solar elements 3 are subsequently fed to the assembly of solar modules 2 with the aid of the sliders 6.

FIGS. 21-27 show an electrostatic station 24 of the device 1. The electrostatic station 24 is used for electrostatically charging and electrostatically discharging the workpiece receptacles 8 of the sliders 6. For this purpose, the electrostatic station 24 has two charging contacts 25 and two discharging contacts 26. Both the charging contacts 25 and the discharging contacts 26 are arranged in a fixed position on the electrostatic station 24. The electrostatic charging of the workpiece receptacles 8 serves to fix the solar elements 3 on the support points 9. The electrostatic charging of the workpiece receptacles 8 makes it possible to reliably fix the solar elements 3 on the support points 9 for feeding by means of electrostatic attraction forces.

For targeted and, above all, reproducible adjustment of the holding forces for electrostatic fixing of the solar elements 3 at the support points 9, the workpiece carriers 8 are first electrostatically discharged. This is carried out via the discharging contacts 26 of the electrostatic station 24.

For electrostatic discharge, the sliders 6 are first positioned below the discharging contacts 26 and then raised by a movement in the direction of the Z-axis until the workpiece receptacles 8 touch the discharging contacts 26.

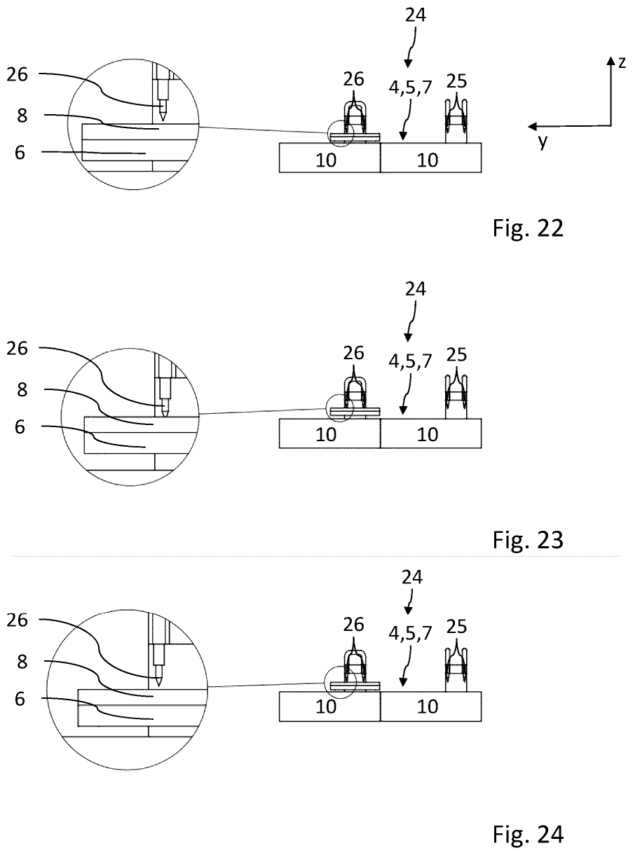

This creates a short circuit that causes the electrostatic discharge of the workpiece receptacles 8. The positioning of the sliders 6 with their workpiece receptacles 8 against the discharging contacts 26 is shown in FIGS. 22-24 and in more detail.

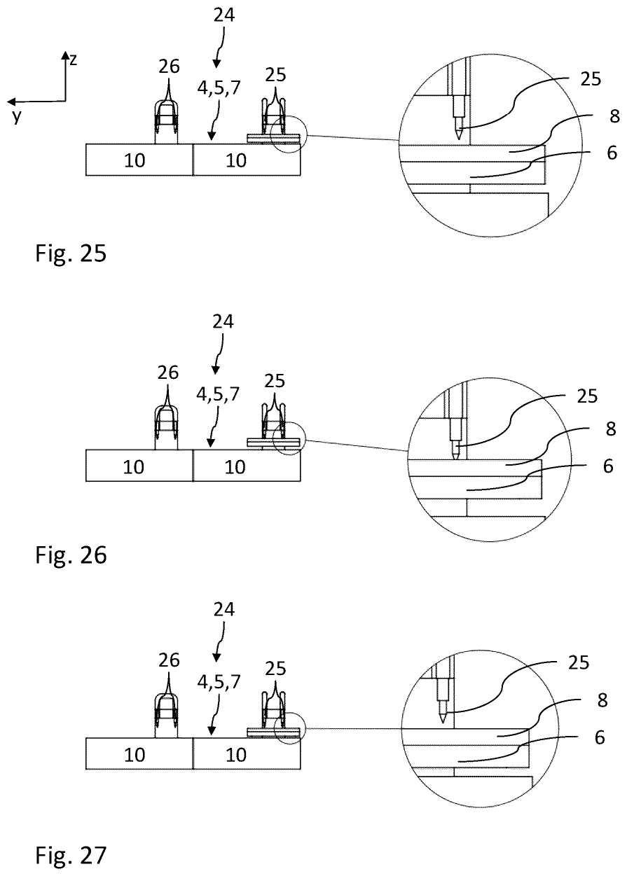

The targeted static charging of the workpiece receptacles 8 sliders 6 is illustrated in FIGS. 25-27. For this purpose, the sliders 6 are first positioned below the charging contacts 25 of the electrostatic station 24. The sliders 6 are then raised in the Z direction until the workpiece receptacles 8 come into contact with the charging contacts 25 of the electrostatic station 24 and can be electrostatically charged. The workpiece receptacles 8 are then ready to receive solar elements 3 on the handling devices 18.

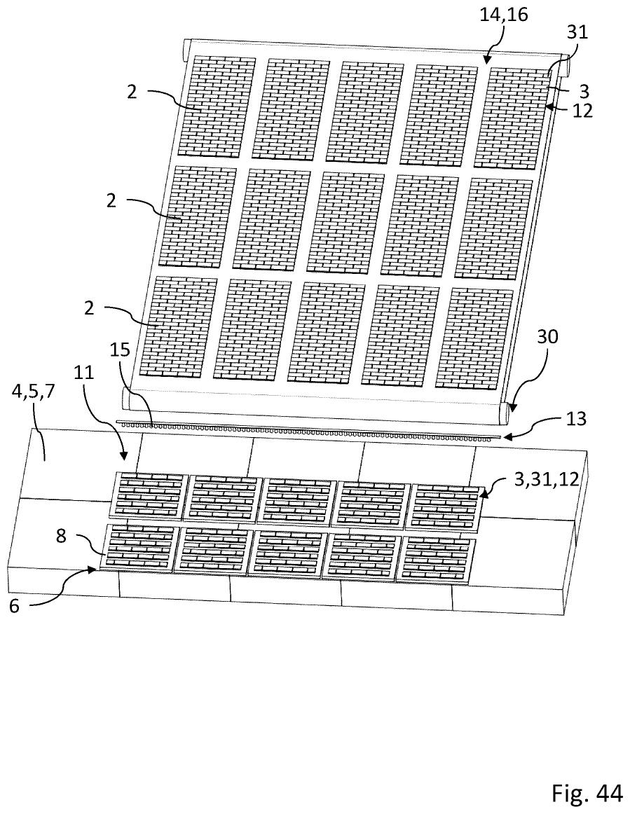

FIGS. 44-49 illustrate that the workpiece receptacles 8 of the sliders 6 are also adapted to hold solar elements 3 in a matrix pattern arrangement of a plurality of solar elements 3. In this way, the solar elements 3 for the assembly of solar modules 2 can be kept ready in the transfer area 11 of the drive surface 7 adjacent to the pick-and-place device 13 in an arrangement that promotes the assembly of solar modules 2 in a matrix arrangement or in a matrix shingle arrangement.

The device 1 also has a plurality of testing devices 27. The testing devices 27 are designed to test the solar elements 3 for damage and/or dimensional accuracy and/or geometry. The testing devices 27 are arranged in the area of the handling devices 18 and are positioned in front of the drive surface 7 of the planar drive 5. In this way, it is possible to inspect the solar elements 3 before they are placed on the support points 9 on the workpiece receptacles 8 of the sliders 6 and to eject solar elements 3 that are found to be improper after the inspection.

The use of the planar drive 5 with its freely and very flexibly positionable sliders 6 also promotes this approach.

Each of the sliders 6 shown in the figures has a plurality of support points 9 for solar elements 3 on its workpiece receptacle 8. Even if individual or multiple support points 9 on the workpiece receptacles 8 of the sliders 6 should remain free due to the ejection of solar elements 3 that are found to be out of order, this can be compensated for by positioning the sliders 6 accordingly in the transfer area 11 adjacent to the pick-and-place device 13. A slider 6 that has a vacant, unoccupied support point 9 can then be moved accordingly to close the gap that is actually present in the provided arrangement of solar elements 3 before the solar elements 3 are removed, so that the placement of solar modules 2 is not impaired by the vacant, unoccupied support point 9.

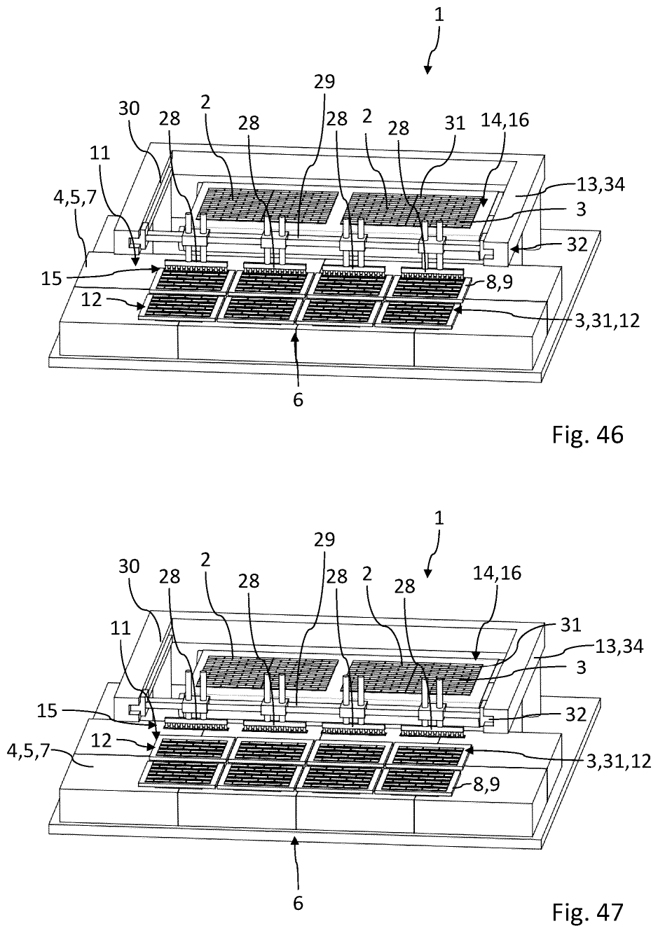

FIGS. 46-49 show a variant of a pick-and-place device 13. The pick-and-place device 13 shown in FIGS. 46-49 is adapted to pick up solar elements 3, 31 held ready in an output arrangement, which are held ready here at the workpiece receptacles 8 of the sliders 6 in a matrix or masonry arrangement, and to deliver them in a defined target arrangement for assembly on a solar module 2. For this purpose, the pick-and-place device 13 has two groups 28 of grippers 15, namely suction pads, the distance between which is variable. In this way, it is possible, to pick up solar elements 3. 31 with the aid of the total of four groups 28 of grippers 15 in an output arrangement and to deposit them in a target arrangement, which differs from the output arrangement, for the assembly of solar modules 2. According to FIGS. 46-49, each group 28 of grippers 15 picks up a row 12 of solar elements 3, 31, which are held ready at a workpiece receptacle 8 of a slider 6, and deposits them by a transfer movement on the base 14, which is provided by the transport unit 16 designed as a conveyor belt.

Two groups 28 of grippers 15 combine the rows 12 of solar elements 3, 31 picked up by them to form a long row 12 during the assembly of a solar module 2. For this purpose, the groups 28 of grippers 15 are brought closer to each other in a movement aligned transversely to the transfer movement.

For this purpose, the pick-and-place device 13 has a linear guide 29, along which the groups 28 of grippers 15 are arranged so that they can be moved relative to one another.

Along the linear guide 29, the groups 28 of grippers 15 can thus be moved transversely or at right angles to a transport direction that is specified by the transport unit 16 downstream of the pick-and-place device 13.

In addition, the groups 28 of grippers 15 can be moved by a transfer guide 30 of a gantry, within which the linear guide 29 can also be moved, in the direction of the transport direction specified by the transport unit 16, i.e. in a separate transfer direction. The transfer guide 30 and the linear guide 29 are aligned at right angles to each other and form a cross-slide guide. which enables the groups 28 of grippers 15 to be moved in two axes.

In the embodiment of a pick-and-place device 13 shown in FIGS. 32-35, it is provided that the grippers 15 are not only movable along a linear axis predetermined by the transfer guide 30, but are also pivotably mounted about a pivot axis aligned transversely to the linear axis predetermined by the transfer guide 30. The pivot axis runs through pivot joints 32.

This promotes the previously explained placement of the solar elements 3 on the base 14 when assembling solar modules 2 in a shingle arrangement, in which rows 12 of solar elements 3 are placed overlapping on already positioned rows 12 of solar elements 3. Incidentally, the previously applied adhesive beads 23 of the solar elements 3 are also provided in the overlapping area between two rows 12, so that the rows 12 of solar elements 3 are electrically connected and bonded together.

In a downstream processing step, the transport unit 16 can then feed the assembled solar module 2, for example, to an active area of the heater 33 or a laminating station or another processing step.

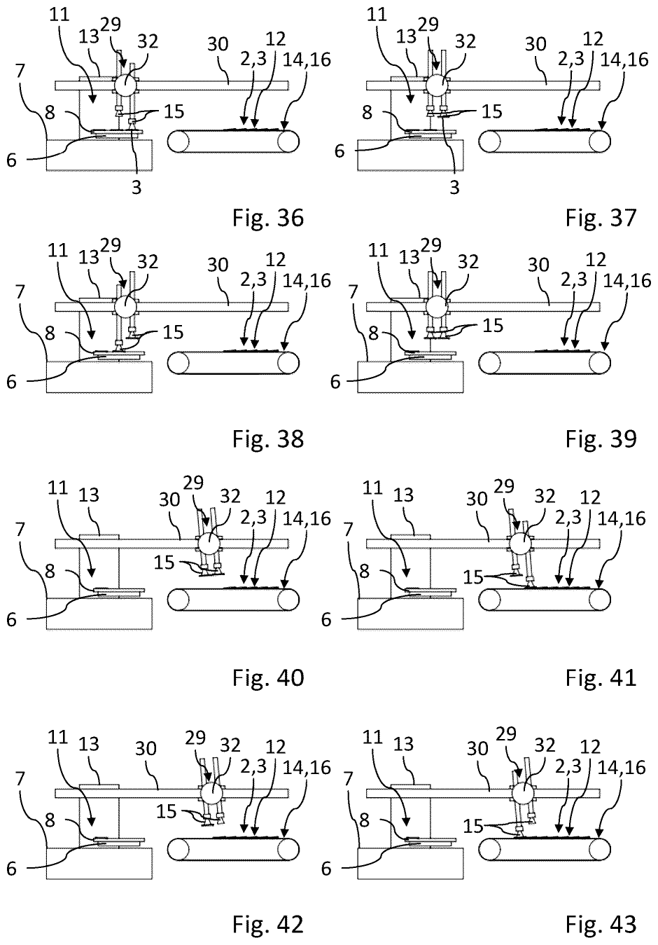

In the embodiment of a pick-and-place device 13 shown in FIGS. 36-43, a total of two rows of grippers 15 are provided. With the aid of the two rows of grippers 15, it is possible to pick up two rows 12 of solar elements 3 one after the other and then place them together on the base 14, which is provided by the transport unit 16. Here too, the two rows of grippers 15 are arranged pivotably on a support structure 34, for example a gantry, of the pick-and-place device 13 via pivot joints 32 in order to promote the shingle arrangement of the rows 12 of solar elements 3 during the placement of solar modules 2.

In order to manufacture solar modules 2, the device 1 described in detail above is set up to carry out the methods described below. Solar modules 2 are fitted with solar elements 3, for example solar shingles, which can also be referred to as solar cell strips.

The solar elements 3 are fed to the assembly of solar modules 2 in accordance with the method using the aforementioned magnetically driven sliders 6 of the magnetically guided planar drive 5.

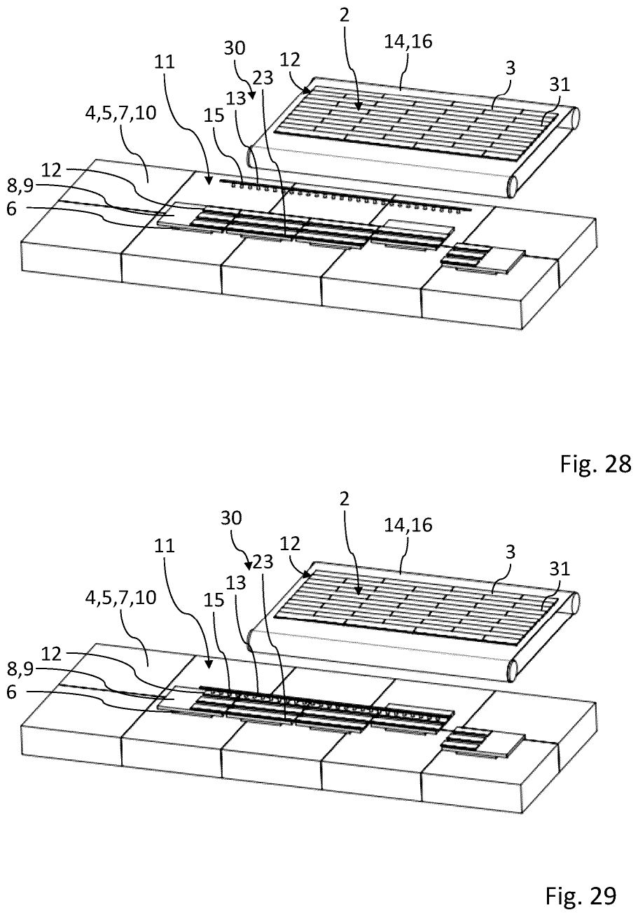

As shown, for example, in FIGS. 28-31 or also in FIGS. 44-49, the solar elements 3 are arranged with the sliders 6 in the previously mentioned transfer area 11 adjacent to the pick-and-place device 13 to form rows 12. The sliders 6 are thus used on the one hand to transport the solar elements 3 to their respective transfer position in the transfer area 11 on the pick-and-place device 13 and on the other hand to provide them in an orientation that is favorable for the row-by-row transfer of the solar elements 3 during the placement of solar modules 2.

The handling devices 18 are used to place the solar elements 3, 31 on the support points 9 on the workpiece receptacles 8 of the sliders 6. Here, an alignment of the solar elements 3, 31 is determined before they are placed on the support points 9 with the aid of the alignment determination device 19 and the sliders 6 are controlled and aligned before the solar elements 3, 31 are placed on the support points 9 in such a way that the sliders 6 are ready to properly pick up the solar elements 3, 31 held in readiness at the handling devices 18 and any misalignment of the solar elements 3 that may be detected can be compensated for when they are placed on the support points 9.

It is thus possible to finally place the solar elements 3 properly positioned on the support points 9. To anticipate the established alignment of the solar elements 3 and to adapt the alignment of the sliders 6 to the alignment of the solar elements 3 on the handling devices 18. it is possible to move the sliders 6 in at least one of six degrees of freedom.

At the adhesive station 21, electrically conductive adhesive is applied to the solar elements 3 in adhesive beads 23. This is carried out by dispensing electrically conductive adhesive from the previously mentioned dispensing nozzles 22. The electrically conductive adhesive is applied to the edges of the individual solar elements 3, 31 in the form of adhesive beads 23. With the aid of the electrically conductive adhesive, it is possible to bond the solar elements 3, 31 to each other row by row in accordance with the shingle arrangement that they will later assume in the assembled solar module 2.

During the application of the electrically conductive adhesive to the solar elements 3, 31, these are positioned accordingly at the dispensing nozzles 22 of the adhesive station 21 with the aid of the sliders 6 and moved past the dispensing nozzles 22, more precisely below the dispensing nozzles 22, for the application of the electrically conductive adhesive in the form of the adhesive bead 23. In this way, the electrically conductive adhesive is applied to the solar elements 3, 31 during a transfer movement of the sliders 6 relative to the dispensing nozzles 22 A defined distance between the solar elements 3, 31 and the dispensing nozzles 22 can be set by moving the sliders 6 along a preferably vertical axis of movement, in this case the Z-axis, of the sliders 6.

The workpiece receptacles 8 of the sliders 6 can be fitted with solar elements 3, 31 and moved with the sliders 6 into a transfer position in the transfer area 11 in such a way that the solar elements 3, 31 form a row 12 of solar elements 3, 31 on two sliders 6 arranged next to each other in the transfer position.

In the exemplary embodiment of the method shown in FIGS. 44-49, at least one offset element 31, i.e. a solar element with shorter dimensions than the other solar elements 3, is provided at least in every second row 12 of solar elements 3, 31, which is kept ready for the assembly of the solar modules 2 with the aid of the sliders 6 in the transfer position in the transfer area 11 adjacent to the pick-and-place device 13, in order to generate a matrix arrangement, in particular a shingle-matrix arrangement, during the assembly of a solar module 2.

In this way, it is possible to produce solar modules 2 with the masonry-like shingle matrix pattern shown in the figures.

To fix the solar elements 3, 31 during transportation, the workpiece receptacles 8 of the sliders 6 are electrostatically charged to a defined value. This takes place in the electrostatic station 24 described above, but the workpiece receptacles 8 are electrostatically discharged beforehand.

To discharge the workpiece receptacles 8, the workpiece receptacles are brought into a contact position with the discharging contacts 26 of the electrostatic station 24 by a corresponding movement of the sliders 6 and then discharged by a short circuit.

The workpiece receptacles 8 are brought into contact with the charging contacts 25 of the electrostatic station 24 by moving the sliders 6 relative to the charging contacts 25 in order to electrostatically charge the workpiece receptacles 8 accordingly.

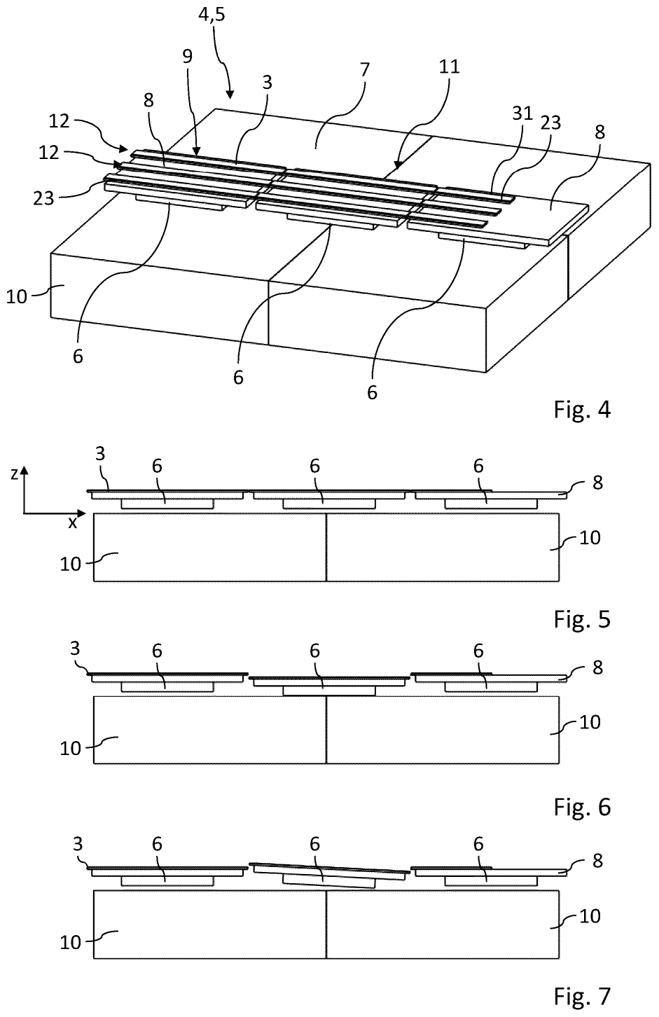

FIGS. 4-7 illustrate that the sliders 6 can perform a compensating movement next to sliders 6 already in the transfer position before moving to a target position in order to avoid a collision between solar elements 3, 31 placed at the support points 9 of the workpiece receptacles 8. Different procedures are possible.

FIG. 6 illustrates that it is possible, for example, to evade the slider 6, which is already in the transfer position, by an evasive movement of the middle slider 6 in the direction of a movement axis that is aligned at right angles to the drive surface 7 of the planar drive 5 and corresponds to the previously mentioned Z-axis. In this way, the middle of the three sliders 6 can be moved into its target position without collision between the solar elements 8 arranged on the workpiece receptacles 8.

Due to the evasive movement, the middle slider 6 is lowered in the direction of the Z-axis compared to the two outer sliders 6.

According to FIG. 7, the central slider 6, which is to be moved to its target position between the already positioned sliders 6, is to be tilted in order to avoid a collision of the solar elements 3, 31 arranged on the workpiece receptacles 8. For this purpose, the slider 6 performs a tilting movement around an axis of movement of the slider 6, which is aligned in the direction of movement of the slider 6 into its target position.

According to FIGS. 44-49, the solar elements 3, 31 can already be arranged on the workpiece receptacles 8 of the sliders 6 in a matrix arrangement, namely in at least two rows and/or offset from one another. This promotes the assembly of the solar modules 2 with solar elements 3, 31 in a matrix shingle arrangement, as shown in FIGS. 44-49.

According to FIGS. 46-49, the solar elements 3, 31 are fed for the assembly of solar modules 2 by transport means, namely by sliders 6 of the magnetically guided planar drive 5. The solar elements 3, 31 are picked up together by at least two sliders 6 in the transfer position and combined to form a row 12 of solar elements 3, 31 for the assembly on a solar module 2. This is carried out by depositing them on the base 14 provided by the transport unit 16.

The solar elements 3, 31 are each picked up together by at least two groups 28 of grippers 15 of the pick-and-place device 13 and combined into a row 12 of solar elements 3, 31 by a relative movement of the groups 28 of grippers 15.

When assembling the solar module 2, the solar elements 3, 31 are placed in such a way that they overlap already placed solar elements 3, 31. The solar elements 3, 31 are also bonded to the solar elements 3, 31 of an already placed row 12 of solar elements 3, 31 during the assembly of the solar module 2. This is carried out by the already positioned solar elements 3, 31 having adhesive beads 23, which are arranged in the overlapping area of the next row 12 of solar elements 3,31, which are subsequently placed on the already positioned solar elements 3,31.

FIGS. 32-35 and 36-43 illustrate that the solar elements 3, 31 are placed on already positioned solar elements 3, 31 during the assembly of a solar module 2 in such a way that their undersides form an acute angle with a base 14 on which the solar elements 3. 31 are placed or deposited for the assembly of solar modules 2.

The device 1 for producing solar modules 2 shown in the figures can be used to carry out a method for producing solar modules 2 as described above.

The invention relates to improvements in the technical field of solar module production. For this purpose, among other things, a device 1 is proposed which has at least two sliders 6 of a magnetically guided planar drive 5 of a feed device 4 of the device 1 for feeding solar elements 3, 31 for the assembly of a solar module 2.

### LIST OF REFERENCE SIGNS

1 Device for the production of solar modules
2 Solar module
3 Solar element, solar shingle
4 Feed device
5 Planar drive
6 Slider
7 Drive surface
8 Workpiece receptacle
9 Support point
10 Drive module
11 Transfer area
12 Rows
13 Pick-and-place device
14 Base
15 Gripper
16 Transport unit, namely conveyor belt
17 Supply station
18 Handling device
19 Alignment determination device
20 Control unit
21 Adhesive station
22 Dispensing nozzle
23 Adhesive bead
24 Electrostatic station
25 Charging contact
26 Discharging contact
27 Testing device
28 Groups of grippers
29 Linear guide
30 Transfer guide
31 Offset element
32 Pivot joint
33 Heater
34 Support structure
35 Testing station
36 Sensor on 35
37 Removal device
38 Suction device
39 Vacuum source
40 Suction means
41 Linear axis on 35

1. A device (1) for producing solar modules (2) from electrically interconnected solar elements (3), the device comprising: a feed device (4) for feeding the solar elements (3) for an assembly of solar modules (2), in-that the feed device (4) comprises a magnetically guided planar drive (5) with at least two magnetically driven sliders (6), wherein each of the sliders (6) has a respective workpiece receptacle (8) on which at least one support point (9) for at least one of the solar elements (3, 31) is formed.

2. The device (1) according to claim 1, wherein at least two of the support points (9) for the at least one solar element (3) are arranged on each of the workpiece receptacles (8).

3. The device (1) according to claim 1, wherein the planar drive (5) is adapted for multi-coordinate positioning of the at least two sliders (6).

4. The device (1) according to claim 1, wherein the magnetically guided planar drive (5) has a drive surface (7) on which the at least two sliders (6) can be positioned independently of each other.

5. The device (1) according to claim 4, wherein a transfer area (11) is defined on the drive surface (7), in which at least two of the sliders (6) are positionable next to one another in rows (11) to configure the solar elements (3) arranged on the support points (9) of the respective workpiece receptacles (8).

6. The device (1) according to claim 1, further comprising a pick-and-place device (13), with which the solar elements (3) arranged on the sliders (6) are removable from the support points (9) and placed on a base (14) for the assembly of solar modules (2), and the pick-and-place device (13) has at least one gripper (15), which is movable in at least two degrees of freedom.

7. The device (1) according to claim 1, further comprising a transport unit (16) on which the solar elements (3) for the assembly of solar modules (2) are placeable.

8. The device (1) according to claim 7, further comprising a suction device (38) with a vacuum source (39) and a suction means (40), which is assigned to the transport unit (16) and is adapted to fix solar elements (3) placed on the transport unit (16) by applying a vacuum to the transport unit (16), and the suction means (40) extends into an effective range of a heater (33) which is provided for curing a bond between solar elements (3) of an assembled solar module (2).

9. The device (1) according to claim 8, wherein the drive surface (7) is formed between a supply station (17) for the solar elements (3) and the pick-and-place device (13).

10. The device (1) according to claim 1, further comprising at least one handling device (18) with at least one gripper (15), with which the solar elements (3) are depositable successively or simultaneously on the support points (9) of the workpiece receptacles (8) of the sliders (6) located in the pick-up position.

11. The device (1) according to claim 10, further comprising an alignment determination device (19) for determining an alignment of the solar elements (3) on the handling device (18).

12. The device (1) according to claim 11, further comprising a control unit (20) which is configured to position at least one of the sliders (6) as a function of a determined alignment of the solar element (3) on the handling device (18) in the pick-up position such that the solar element (3) is placed in the correct alignment on the support point (9), without realignment of the solar element (3) on and/or with the handling device (18).

13. The device (1) according to claim 1, further comprising an adhesive station (21) which has at least one dispensing nozzle (22) for dispensing electrically conductive adhesive onto at least one of the solar elements (3) arranged at the support point (9).

14. The device (1) according to claim 13, wherein the adhesive station (21) has a number of the dispensing nozzles (22) which corresponds to a number of the support points (9) on the workpiece receptacle (8), and at least two of the dispensing nozzles (22) are arranged offset relative to one another in a direction of movement of the sliders (6) through the adhesive station (21).

15. The device (1) according to claim 1, further comprising an electrostatic station (24) which is adapted for electrostatically charging and/or electrostatically discharging the workpiece receptacles (8) of the sliders (6), and the electrostatic station (24) has at least one charging contact (25) and/or at least one discharging contact (26).

16. The device (1) according to claim 1, wherein the workpiece receptacles (8) of the sliders (6) are adapted to receive a matrix pattern comprising a plurality of solar elements (3).

17. The device (1) according to claim 1, further comprising at least one testing device (27) for testing the solar elements (3) for at least one of damage, dimensional accuracy, or geometry.

18. The device (1) according to claim 1, further comprising at least one testing station (35) which is configured for at least one of testing an adhesive application on the solar elements (3) arranged on the tool receptacles (8) or testing the solar elements (3) arranged on the tool receptacles (8).

19. The device (1) according to claim 18, wherein the testing station (35) has at least one sensor (36) for testing the solar elements (3) and/or an adhesive application on the solar elements (3).

20. The device (1) according to claim 19, wherein the testing station (35) is assigned a removal device (37) which is adapted to eject improper solar elements (3), and the removal device (37) has at least one gripper (15).

21. The device (1) according to claim 1, further comprising: a pick-and-place device (13), with which solar elements (3) held ready in an output arrangement are picked up and placed in a defined target arrangement for the assembly of one of the solar modules (2), which has at least two groups (28) of grippers (15), a distance between which is variable in order to pick up the solar elements (3) in an output arrangement and deliver them in a target arrangement, which differs from the output arrangement, for the assembly of the solar module (2).

22. The device (1) according to claim 21, wherein the pick-and-place device (13) has at least one of a linear guide (29) along which the groups (28) of grippers (15) are arranged so as to be displaceable relative to one another in a first direction, or a transfer guide along which the groups (28) of grippers (15) are displaceable in a second direction.

23. The device (1) according to claim 22, wherein the groups (28) of grippers (15) are movable at least one of transversely or at right angles to a transport direction of one of the transport unit (16) downstream of the pick-and-place device (13) or in a transfer direction.

24. A method for producing solar modules (2), the method comprising: fitting solar modules (2) with solar elements (3), and feeding the solar elements (3) for the assembly of the solar modules (2) with magnetically driven sliders (6) of a magnetically guided planar drive (5).

25. The method according to claim 24, further comprising at least one of arranging the solar elements (3) with the sliders (6) in at least one row (12) or transporting the solar elements (3) to a transfer position on a pick-and-place device (13).

26. The method according to claim 24, further comprising placing the solar elements (3) on support points (9) on workpiece receptacles (8) of the sliders (6).

27. The method according to claim 26. further comprising determining an alignment of the solar elements (3) before the solar elements are placed on the support points (9) and the controlling and aligning sliders (6) before the solar elements (3) are placed on the support points (9) such that a detected misalignment of the solar elements (3) is compensated for when they are placed on the support points (9), so that the solar elements (3) are correctly positioned on the support points (9).

28. The method according to claim 26, further comprising applying electrically conductive adhesive from at least one dispensing nozzle (22) of an adhesive station (21) to the solar elements (3) which are positioned on the support points (9) of the workpiece receptacles (8) of the sliders (6), wherein at least one of the adhesive is applied during a transfer movement of the slider (6) relative to the dispensing nozzle (22), or a defined distance between the solar elements (3) and the at least one dispensing nozzle (22) is set by moving the sliders (6) along an axis of movement of the sliders (6).

29. The method according to claim 24, further comprising feeding the solar elements (3) with the sliders (6) to a testing station (35), in which an inspection of at least one of the solar elements (3) or of an adhesive application on the solar elements (3) is carried out.

30. The method according to claim 24, wherein the workpiece receptacles (8) of the sliders (6) are loaded with solar elements (3) and moved with the sliders (6) into a transfer position such that solar elements (3) on two of the sliders (6) arranged next to each other in the transfer position form at least one row (12) of the solar elements (3).

31. The method according to claim 24, further comprising, for generating a matrix arrangement in the assembly of one of the solar modules (2), at least one offset element (31), comprising a solar element with shorter dimensions than other ones of the solar elements (3), is provided in at least every second row (12) of solar elements (3) which is held ready in the transfer position for the assembly of the solar modules (2).

32. The method according to claim 24, further comprising electrostatically charging the workpiece receptacles (8) of the sliders (6), for transport fixing of the solar elements (3) on the support points (9).

33. The method according to claim 24, wherein at least one of the sliders (6) executes an evasive movement before moving the slider (6) into the target position next to one of the sliders (6) already in the transfer position in order to avoid a collision between solar elements (3) placed at the support points (9) of the workpiece receptacles (8).

34. The method according to claim 33, wherein the evasive movement of the at least one slider (6) is at least one of a tilting movement about an axis of movement of the at least one slider (6) or a linear movement in a spatial axis about an axis of movement aligned in a direction of movement of the one slider (6) into the target position.

35. The method according to claim 34, wherein one of the sliders (6), before being moved into the target position between two of the sliders (6) already in the transfer position, is at least one of tilted about an axis of movement into the target position, or is at least one of raised or lowered in order to avoid a collision between the at least one solar element (6) arranged on the workpiece receptacle (8) and ones of the solar elements (3) arranged on the workpiece receptacles (8) of the sliders (6) already in the transfer position.

36. The method according to claim 24, further comprising arranging the solar elements (3) in a matrix arrangement on a workpiece receptacle (8) of at least one of the sliders (6).

37. The method according to claim 24, wherein the solar elements (3) are fed for an assembly of the solar modules (2) by transport means (6) including the sliders (6) of the magnetically guided planar drive (5), wherein the solar elements (3) are jointly picked up by at least two transport of the means (6) located in a transfer position and are combined to form a row (12) of the solar elements (3) for the assembly of one of the solar modules (2).

38. The method according to claim 37, further comprising picking up the solar elements (3) together with at least two groups (28) of grippers (15) of a pick-and-place device (13) and are combined by a relative movement of the groups (28) of grippers (15) to form the row (12) of the solar elements (3).

39. The method according to claim 38, wherein the solar elements (3) are placed during the assembly of one of the solar modules (2) such that the solar elements overlap already placed ones of the solar elements (3) and/or the solar elements (3) are glued together during the assembly of the solar module (2).

40. The method according to claim 39, wherein the solar elements (3) are placed on already positioned ones of the solar elements (3) during the assembly of one of the solar modules (2) such that undersides thereof form an acute angle with a base (14) on which the solar elements (3) are deposited while being placed.

41. (canceled)
